(19) United States
(12) Patent Application Publication
(10) Pub. No.: US 2017/0059628 A1
(43) Pub. Date: Mar. 2, 2017

(54) POWER DETECTION APPARATUS

(71) Applicants: BOE TECHNOLOGY GROUP CO., LTD., Beijing (CN); CHONGQING BOE OPTOELECTRONICS TECHNOLOGY CO., LTD., Beibei (CN)

(72) Inventor: Bo XU, Beijing (CN)

(21) Appl. No.: 15/184,565

(22) Filed: Jun. 16, 2016

(30) Foreign Application Priority Data
Aug. 31, 2015 (CN) 201510546232.1

(51) Int. Cl. G01R 15/20; G01R 21/06

(52) U.S. Cl. CPC G01R 15/202; G01R 21/06

(57) ABSTRACT

A power detection apparatus includes: a voltage detection unit configured to detect a voltage of a component to be tested on a circuit board and output a first voltage value; a current detection unit configured to detect a current of the component to be tested and output a second voltage value; a processing unit configured to calculate a power of the component to be tested according to the first and second voltage values; the current detection unit includes a first Hall sensor, a second Hall sensor and an amplifying circuit; a negative electrode of the second Hall sensor is connected to the power supply, a positive electrode of the second Hall sensor is connected to a second input terminal of the amplifying circuit, and an output terminal of the amplifying circuit is connected to the processing unit. The power detection apparatus can realize a power measurement for Micro-power components.

### TECHNICAL FIELD

The present disclosure relates to a field of power detection, and more particularly to a power detection apparatus.

### BACKGROUND

As a utilization of LCD (Liquid Crystal Display) products has become more and more widespread, decreasing in power consumption of various LCD products is also taken more and more attention of consumers, and has become an important goal for manufacturers to develop a low-power consumption product. To reduce the power consumption of the LCD products, power consumption of respective portions, such as a circuit board, a driving circuit, a backlight source, etc., in the LCD product must be analyzed at first. Specifically, the power consumption of main components on the circuit board is required to be analyzed in the analyzing of the power consumption of the LCD circuit board.

Existing measurements for the power consumption are implemented with a power meter, however, a general power meter only can measure the power consumption of the LCD product as a whole, but fails to measure the power consumption for respective micro-power elements in the LCD products due to a limitation of the power meter in its current measurement scope when the power meter measures the power consumption.

### SUMMARY

In order to measure power consumption of micro-power elements in a circuit board, embodiments of the present disclosure provide a power detection apparatus, comprising: a voltage detection unit configured to detect a voltage of a component to be tested on a circuit board and output a first voltage value; a current detection unit configured to detect a current of the component to be tested and output a second voltage value; a processing unit configured to calculate a power of the component to be tested according to the first voltage value output from the voltage detection unit and the second voltage value output from the current detection unit; the current detection unit comprises a first Hall sensor, a second Hall sensor and an amplifying circuit, and the first and second Hall sensors are disposed close to an input line of the component to be tested; a positive electrode of the first Hall sensor is connected to a power supply, a negative electrode of the first Hall sensor is connected to a first input terminal of the amplifying circuit; a negative electrode of the second Hall sensor is connected to the power supply, a positive electrode of the second Hall sensor is connected to a second input terminal of the amplifying circuit, and an output terminal of the amplifying circuit is connected to the processing unit.

In one implementation of an embodiment of the present disclosure, the amplifying circuit comprises one one-stage operational amplifier and two two-stage operational amplifiers, inverting input terminals of the two two-stage operational amplifiers are connected with each other, output terminals of the two two-stage operational amplifiers are connected to two input terminals of the one-stage operational amplifier, respectively, and non-inverting input terminals of the two two-stage operational amplifiers function as a first input terminal and a second input terminal of the amplifying circuit respectively.

In another implementation of an embodiment of the present disclosure, the one-stage operational amplifier and the two two-stage operational amplifiers are precision operational amplifiers.

In another implementation of an embodiment of the present disclosure, the voltage detection unit comprises a first resistor and a second resistor, wherein one terminal of the first resistor is connected to one terminal of the second resistor, the other terminal of the first resistor is electrically connected with the input line of the component to be tested, the other terminal of the second resistor is grounded, and an output terminal of the voltage detection unit is connected between the first and second resistors.

In another implementation of an embodiment of the present disclosure, the processing unit is further configured to: determine a voltage value of the component to be tested according to the first voltage value and resistances of the first and second resistors; determine a current value of the component to be tested according to the second voltage value; and calculate the power of the component to be tested according to the determined voltage value and current value of the component to be tested.

In another implementation of an embodiment of the present disclosure, the processing unit is further configured to: acquire a correspondence relationship between the second voltage values output from the current detection unit and current values of the component to be tested; and determine the current value of the component to be tested, corresponding to the second voltage value.

In another implementation of an embodiment of the present disclosure, the power detection apparatus further comprises two Analog Digital Converters (ADCs), wherein one is connected between the current detection unit and the processing unit, and the other is connected between the voltage detection unit and the processing unit.

In another implementation of an embodiment of the present disclosure, the power detection apparatus further comprises a display unit configured to display the calculated power of the component to be tested.

In another implementation of an embodiment of the present disclosure, the power of the component to be tested comprises at least one of an instantaneous power, an average power, a minimum power and a maximum power of the component to be tested.

In another implementation of an embodiment of the present disclosure, the component to be tested is an integrated circuit in a Liquid Crystal Display (LCD).

According to solutions provided in an embodiment of the present disclosure, the voltage and current of the component to be tested on a circuit board can be detected respectively, then the current and voltage of the component to be tested can be calculated according to the two output voltage values, and the power can be calculated and displayed finally. Particularly, the current detection unit measures the current with magnetic effects of the Hall sensors, wherein the two Hall sensors are disposed close to the input line of the component to be tested, the positive electrode of the first Hall sensor is connected to the power supply, the negative electrode of the first Hall sensor is connected to the first input terminal of the amplifying circuit, the negative electrode of the second Hall sensor is connected to the power supply, and the positive electrode of the second Hall sensor is connected to the second input terminal of the amplifying circuit. When the same current flows through two Hall sensors, the output of one Hall sensor would become smaller and that of the other Hall sensor would become greater, and thus a difference occurs between the outputs of the two Hall sensors, the difference is amplified via the amplifying circuit and input to the processing unit for a current calculation. The power (current) measurement for the micro-power component can be realized with the Hall sensor, and then a measurement precision can be ensured by the amplifying processing.

### BRIEF DESCRIPTION OF THE DRAWINGS

In order to explain solutions in embodiments of the present disclosure more clearly, drawings required for describing an embodiment of the present disclosure will be introduced briefly below. Obviously, the drawings described below are only some embodiments of the present disclosure, and those ordinary skilled in the art can obtain other drawings according to these drawings without any inventive labors.

FIG. 1 is an exemplary view illustrating a configuration of a power detection apparatus according to an embodiment of the present disclosure;

FIG. 2 is an exemplary view illustrating a configuration of another power detection apparatus according to an embodiment of the present disclosure;

FIG. 3 is an exemplary view illustrating a configuration of a current detection unit according to an embodiment of the present disclosure; and

FIG. 4 is an exemplary view illustrating a configuration of a voltage detection unit according to an embodiment of the present disclosure.

### DETAILED DESCRIPTION

Thereafter, implementations of the present disclosure will be described clearly and completely in connection with drawings in order to explain objects, solutions and advantages of the present disclosure more clearly.

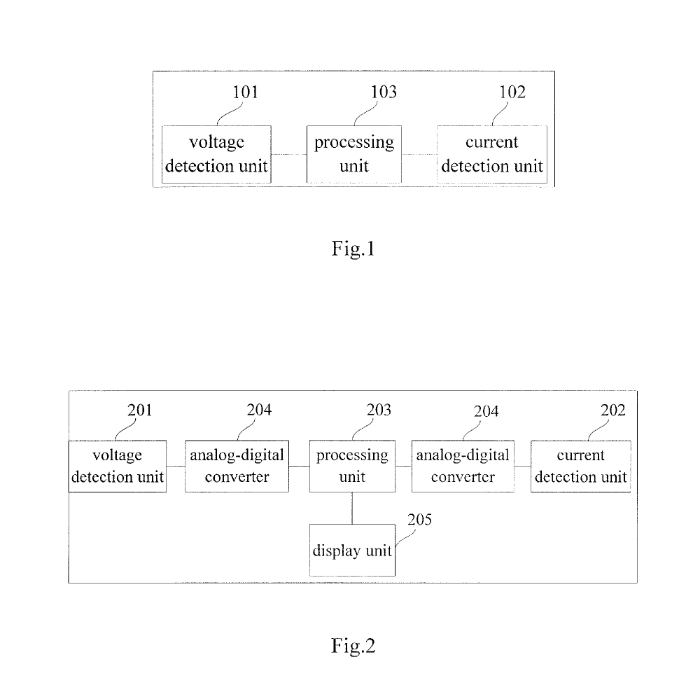

FIG. 1 is an exemplary view illustrating a configuration of a power detection apparatus according to an embodiment of the present disclosure. Referring to FIG. 1, the power detection apparatus comprises:

a voltage detection unit 101 configured to detect a voltage of a component to be tested on a circuit board and output a first voltage value;

a current detection unit 102 configured to detect a current of the component to be tested and output a second voltage value;

a processing unit 103 configured to calculate a power of the component to be tested according to the first voltage value output from the voltage detection unit and the second voltage value output from the current detection unit;

the current detection unit 102 comprises a first Hall sensor, a second Hall sensor and an amplifying circuit, wherein the first and second Hall sensors are disposed close to an input line of the component to be tested, a positive electrode of the first Hall sensor is connected to a power supply, a negative electrode of the first Hall sensor is connected to a first input terminal of the amplifying circuit, a negative electrode of the second Hall sensor is connected to the power supply, a positive electrode of the second Hall sensor is connected to a second input terminal of the amplifying circuit, and an output terminal of the amplifying circuit is connected to the processing unit.

According to the solution provided in an embodiment of the present disclosure, the voltage value and current value of the component to be tested on a circuit board can be detected respectively, then the current and voltage of the component to be tested can be calculated according to two output voltage values, and the power can be calculated and displayed finally. Particularly, the current detection unit measures the current with magnetic effect of the Hall sensor, wherein two Hall sensors are disposed close to the input line of the component to be tested, the positive electrode of the first Hall sensor is connected to the power supply, the negative electrode of the first Hall sensor is connected to the first input terminal of the amplifying circuit, the negative electrode of the second Hall sensor is connected to the power supply, the positive electrode of the second Hall sensor is connected to the second input terminal of the amplifying circuit. The output of one Hall sensor would become smaller and that of the other Hall sensor would become greater when a current flows through them, and thus a difference occurs between the two Hall sensors and is input to the processing unit after being amplified via the amplifying circuit for a current calculation. The power (current) measurement for the micro-power consumption component can be realized with the Hall sensor, and then a measurement precision can be ensured by the amplifying processing.

FIG. 2 is an exemplary view illustrating a configuration of another power detection apparatus according to an embodiment of the present disclosure. Referring to FIG. 2, the apparatus comprises:

a voltage detection unit 201 configured to detect a voltage of a component to be tested on a circuit board and output a first voltage value;

a current detection unit 202 configured to detect a current of the component to be tested and output a second voltage value; and

a processing unit 203 configured to calculate a power of the component to be tested according to the first voltage value output from the voltage detection unit and the second voltage value output from the current detection unit.

Optionally, the first and second voltage values are the outputs of the voltage detection unit 201 and the current detection unit 202, respectively, and the processing unit 203 calculates the voltage and current of the component to be tested according to the first and second voltage values, to implement the power calculation of the component to be tested, and the detailed calculation would be described later.

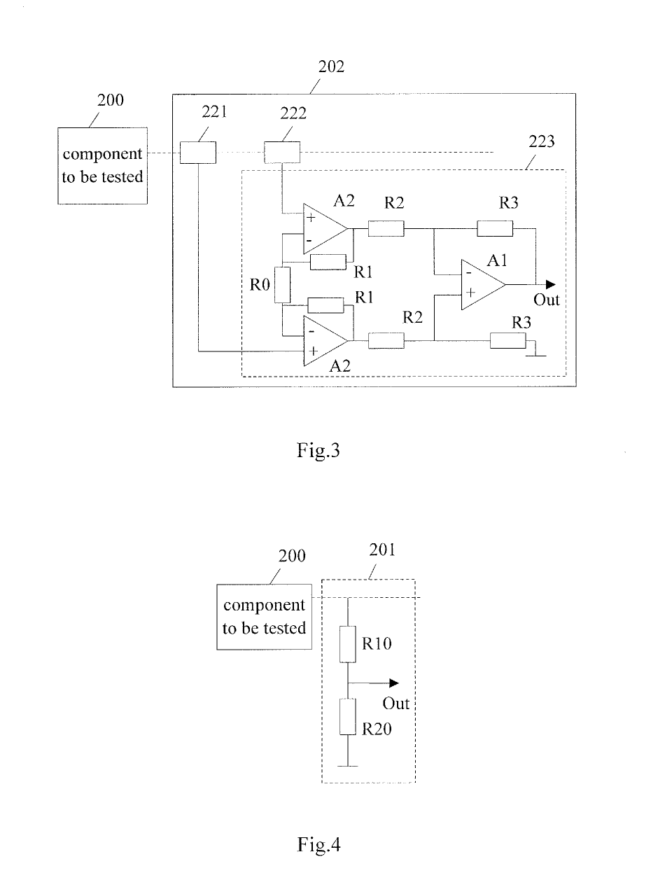

FIG. 3 is an exemplary view illustrating a configuration of the current detection unit 202 according to an embodiment of the present disclosure. Referring to FIG. 3, the current detection unit 202 comprises a first Hall sensor 221, a second Hall sensor 222 and an amplifying circuit 223, wherein the first and second Hall sensors, 221 and 222, are disposed close to an input line of the component to be tested, a positive electrode of the first Hall sensor 221 is connected to a power supply, a negative electrode of the first Hall sensor 221 is connected to a first input terminal of the amplifying circuit, a negative electrode of the second Hall sensor is 222 connected to the power supply, a positive electrode of the second Hall sensor 222 is connected to a second input terminal of the amplifying circuit, and an output terminal of the amplifying circuit 223 is connected to the processing unit 203.

Optionally, the first Hall sensor 221 and the second Hall sensor 222 can be the same type of Hall sensors. The first Hall sensor 221 and the second Hall sensor 222 can cover the input line of the component to be tested, for example, the first Hall sensor 221 and the second Hall sensor 222 can be adhered to the input line of the component to be tested, and such a disposition manner enables an installation of the first Hall sensor 221 and the second Hall sensor 222 to be convenient.

Optionally, the power supply to which the first Hall sensor 221 and the second Hall sensor 222 are connected can be a power supply for the power detection apparatus, no electrical connections exist between the component to be tested and the first Hall sensor 221 and the second Hall sensor 222, and input currents for the first Hall sensor 221 and the second Hall sensor 222 are set according to the actual requirements. Furthermore, the first Hall sensor 221 and the second Hall sensor 222 also comprise ground terminals.

In a case in which the current is detected with a single Hall sensor, a relationship between the current of the component to be tested and the output voltage of the Hall sensor is as follows: the output voltage is 2.5V if the current is 0, and a change in the output voltage of the Hall sensor would be ΔV=kΔI if a change in the current is ΔI, wherein K is a Hall coefficient.

In a case in which the current is detected with two Hall sensors, the change in the output voltage of the first Hall sensor would be ΔV₁=k₁ΔI and the change in the output voltage of the second Hall sensor would be ΔV2=−k₂ΔI if the change in the current is ΔI, therefore the change in the voltage would be ΔV₁−ΔV₂=k₁ΔI+k₂ΔI. It can be seen that the second voltage value output from the current detection unit 202 is enhanced when the measurement is implemented with two Hall sensors, a detection error is reduced, so that the current detection is more precise. Herein, k₁ and k₂ are Hall coefficient.

Referring to FIG. 3 again, the amplifying circuit 223 comprises one one-stage operational amplifier A1 and two two-stage operational amplifiers A2, wherein inverting input terminals of the two two-stage operational amplifiers A2 are connected with each other, output terminals of the two two-stage operational amplifiers A2 are connected to two input terminals of the one-stage operational amplifier A1, respectively, and non-inverting input terminals of the two two-stage operational amplifiers A2, as a first input terminal and a second input terminal of the amplifying circuit, are respectively connected to the first Hall sensor 221 and the second Hall sensor 222. In the present disclosure, signals are amplified with the amplifying circuit described above so as to realize the measurement for the current.

Optionally, the one-stage operational amplifier A1 and the two two-stage operational amplifiers A2 can be precision operational amplifiers. The amplifying circuit formed with the precision operational amplifiers can amplify tiny signals, and further, the precision operational amplifying circuit can restrain a zero drift.

Furthermore, besides the one-stage operational amplifier A1 and the two-stage operational amplifier A2, the amplifying circuit 223 further comprises a resistor R0, two resistors R1, two resistors R2 and two resistors R3, wherein the resistor R0 is connected between the inverting input terminals of the two two-stage operational amplifiers A2, the two resistors R1 are connected between the respective inverting input terminals and the corresponding output terminals of the two two-stages operational amplifiers A2, the two resistors R2 are connected between the respective output terminals of the two two-stage operational amplifiers A2 and the input terminals of the one-stage operational amplifier A1, one resistor R3 is connected between the inverting input terminal and the output terminal of the one-stage operational amplifier A1, and the other resistor R3 is connected between the non-inverting input terminal of the one-stage operational amplifier A1 and the ground. Herein the resistors R0, R1 and R3 are feedback resistors, and the resistors R2 are voltage-dividing resistors.

In an embodiment of the present disclosure, a gain value of the amplifying circuit can be set depending on the actual situation.

FIG. 4 is an exemplary view illustrating a structure of the voltage detection unit 201 according to an embodiment of the present disclosure. Referring to FIG. 4, the voltage detection unit 201 comprises a first resistor R10 and a second resistor R20, one terminal of the first resistor R10 is connected to one terminal of the second resistor R20, the other terminal of the first resistor RIO is electrically connected with an input line of the component to be tested, the other terminal of the second resistor R20 is grounded, and an output terminal of the voltage detection unit 201 is connected between the first resistor R10 and the second resistor R20. Since the voltage of the component to be tested is detected with the above voltage divider measurement circuit, a circuit structure is simple and it is convenient to measure the voltage of the component to be tested.

In an embodiment of the present disclosure, besides the above voltage divider measurement circuit, the voltage detection unit 201 can be realized with Hall voltage sensors.

In an embodiment of the present disclosure, the processing unit 203 is further configured to:

determine a voltage value of the component to be tested according to the first voltage value and resistances of the first and second resistors;

determine a current value of the component to be tested according to the second voltage value; and

calculate the power of the component to be tested according to the determined voltage value and current value of the component to be tested.

In an example, the processing unit 203 can calculate the voltage value of the component to be tested by a formula U1/U=R20/(R10+R20), wherein U1 is the first voltage value and U is the voltage value of the component to be tested.

In an example, the processing unit 203 is further configured to:

acquire a correspondence relationship between the second voltage values output from the current detection unit and current values of the component to be tested; and

determine the current value of the component to be tested, corresponding to the second voltage value.

In an example, the correspondence relationship between the second voltage values output from the current detection unit and the current values of the component to be tested can be acquired by an experimental calibration in advance, and can be preset inside the processing unit 203 for being used in the measurement.

Additionally, as illustrated in FIG. 2, the power detection apparatus further comprises two Analog Digital Converters (ADCs) 204, one ADC 204 is connected between the current detection unit 202 and the processing unit 203, and the other ADC 204 is connected between the voltage detection unit 201 and the processing unit 203. The ADC is used to convert the output voltage value into a digital signal so as to be input to the processing unit for the subsequent processing.

In an example, the processing unit 203 can be a CPU (Central Processing Unit).

Further, as illustrated in FIG. 2, the power detection apparatus further comprises a display unit 205 configured to display the calculated power of the component to be tested. The display unit 205 can display the measured power intuitively, which is convenient for operators to observe and record.

In an example, the display unit 205 can be a display or a PC (Personal Computer). After the power is calculated by the processing unit 203, it would be transferred to the display unit 205 via an interface(s) (such as a USB (Universal Serial Bus)) for displaying.

In an embodiment of the present disclosure, the power of the component to be tested can comprise at least one of an instantaneous power, an average power, a minimum power or a maximum power of the component to be tested.

Particularly, the instantaneous power is a product of the current and voltage of the component to be tested, the average power can be acquired by averaging a plurality of measured instantaneous power, the minimum power and the maximum power are the minimum value and the maximum value among the plurality of measured instantaneous power, respectively.

In an embodiment of the present disclosure, the component to be tested can be an IC (Integrated Circuit) in a Liquid Crystal Display (LCD). Therefore, by the above apparatus, it can be realized that the power of elements on a LCD device (for example, a driving circuit board) is measured online, and the result can be displayed intuitively, which is convenient to use, so that the power of the low-power component can be measured simply and a distribution of the power consumption of the LCD elements can be analyzed conveniently; thus, a design can be optimized or alerted by taking the related power situations into account and the design for the LCD driving circuit can be enhanced.

Those ordinary skilled in the art can understand that all or part of steps for implementing the embodiment described above can be realized by hardware, or can also be implemented by instructing related hardware through the program stored in a computer readable storage medium, wherein the storage medium can be a Read Only Memory, a magnetic disk or an optical disk, etc.

The above descriptions only illustrate the specific embodiments of the present disclosure, and the protection scope of the present disclosure is not limited thereto. All the modifications, equivalent substitution, improvements should be covered by the protection scope of the disclosure as long as they fall into the spirits and principles of the present disclosure.

What is claimed is:

1. A power detection apparatus, comprising:
a voltage detection unit configured to detect a voltage of a component to be tested on a circuit board and output a first voltage value;
a current detection unit configured to detect a current of the component to be tested and output a second voltage value;
a processing unit configured to calculate a power of the component to be tested according to the first voltage value output from the voltage detection unit and the second voltage value output from the current detection unit;
wherein the current detection unit comprises a first Hall sensor, a second Hall sensor and an amplifying circuit, the first and second Hall sensors are disposed close to an input line of the component to be tested; a positive electrode of the first Hall sensor is connected to a power supply, and a negative electrode of the first Hall sensor is connected to a first input terminal of the amplifying circuit; a negative electrode of the second Hall sensor is connected to the power supply, and a positive electrode of the second Hall sensor is connected to a second input terminal of the amplifying circuit; an output terminal of the amplifying circuit is connected to the processing unit.

2. The power detection apparatus of claim 1, wherein the amplifying circuit comprises one one-stage operational amplifier and two two-stage operational amplifiers, wherein inverting input terminals of the two two-stage operational amplifiers are connected with each other, output terminals of the two two-stage operational amplifiers are connected to two input terminals of the one-stage operational amplifier, respectively, and non-inverting input terminals of the two two-stage operational amplifiers function as the first input terminal and the second input terminal of the amplifying circuit respectively.

3. The power detection apparatus of claim 2, wherein the one-stage operational amplifier and the two two-stage operational amplifiers are precision operational amplifiers.

4. The power detection apparatus of claim 1, wherein the voltage detection unit comprises a first resistor and a second resistor, wherein one terminal of the first resistor is connected to one terminal of the second resistor, the other terminal of the first resistor is electrically connected with the input line of the component to be tested, and the other terminal of the second resistor is grounded; an output terminal of the voltage detection unit is connected between the first and second resistors.

5. The power detection apparatus of claim 4, wherein the processing unit is further configured to:
determine a voltage value of the component to be tested according to the first voltage value and resistances of the first and second resistors;
determine a current value of the component to be tested according to the second voltage value; and
calculate the power of the component to be tested according to the determined voltage value and current value of the component to be tested.

6. The power detection apparatus of claim 5, wherein the processing unit is further configured to:
acquire a correspondence relationship between the second voltage values output from the current detection unit and current values of the component to be tested; and
determine the current value of the component to be tested, corresponding to the second voltage value.

7. The power detection apparatus of claim 1, wherein the power detection apparatus further comprises two Analog Digital Converters, wherein one is connected between the current detection unit and the processing unit, and the other is connected between the voltage detection unit and the processing unit.

8. The power detection apparatus of claim 1, wherein the power detection apparatus further comprises a display unit configured to display the calculated power of the component to be tested.

9. The power detection apparatus of claim 1, wherein the power of the component to be tested comprises at least one of an instantaneous power, an average power, a minimum power and a maximum power of the component to be tested.

10. The power detection apparatus of claim 1, wherein the component to be tested is an integrated circuit in a Liquid Crystal Display.

11. The power detection apparatus of claim 2, wherein the voltage detection unit comprises a first resistor and a second resistor; one terminal of the first resistor is connected to one terminal of the second resistor, the other terminal of the first resistor is electrically connected with the input line of the component to be tested, and the other terminal of the second resistor is grounded; an output terminal of the voltage detection unit is connected between the first and second resistors.

12. The power detection apparatus of claim 11, wherein the processing unit is further configured to:
determine a voltage value of the component to be tested according to the first voltage value and resistances of the first and second resistors;
determine a current value of the component to be tested according to the second voltage value; and
calculate the power of the component to be tested according to the determined voltage value and current value of the component to be tested.

13. The power detection apparatus of claim 12, wherein the processing unit is further configured to:
acquire a correspondence relationship between the second voltage values output from the current detection unit and current values of the component to be tested; and
determine the current value of the component to be tested, corresponding to the second voltage value.

14. The power detection apparatus of claim 2, wherein the power detection apparatus further comprises two Analog Digital Converters; wherein one is connected between the current detection unit and the processing unit, and the other is connected between the voltage detection unit and the processing unit.

15. The power detection apparatus of claim 2, wherein the power detection apparatus further comprises a display unit configured to display the calculated power of the component to be tested.

16. The power detection apparatus of claim 2, wherein the power of the component to be tested comprises at least one of an instantaneous power, an average power, a minimum power and a maximum power of the component to be tested.

17. The power detection apparatus of claim 2, wherein the component to be tested is an integrated circuit in a Liquid Crystal Display.
